(19) United States
(12) Patent Application Publication
(10) Pub. No.: US 2025/0380454 A1
(43) Pub. Date: Dec. 11, 2025

(54) PARASITIC CAPACITENCE REDUCTION IN STACKED TRANSISTOR

(71) Applicant: International Business Machines Corporation, Armonk, NY (US)

(72) Inventors: WuKang Kim, Albany, NY (US); Ruilong Xie, Niskayuna, NY (US); Chen Zhang, Santa Clara, CA (US); Nicholas Alexander POLOMOFF, Hopewell Junction, NY (US)

(21) Appl. No.: 18/736,110

(22) Filed: Jun. 6, 2024

(51) Int. Cl. H01L 29/417; H01L 21/822; H01L 21/8238; H01L 23/528; H01L 27/06; H01L 27/092; H01L 29/06; H01L 29/423; H01L 29/66; H01L 29/775; H01L 29/786

(52) U.S. Cl. CPC H10D 30/6729; H01L 23/5283; H10D 30/014; H10D 30/43; H10D 30/6735; H10D 30/6757; H10D 62/121; H10D 84/0186; H10D 84/038; H10D 84/856; H10D 88/00; H10D 88/01

(57) ABSTRACT

A semiconductor IC structure may include a first stacked transistor and a second stacked transistor. A conductive contact is at least partially between the first stacked transistor and the second stacked transistor. The conductive contact includes a deep via and an airgap spacer exists around the deep via and is in contact with respective source/drain regions and gates of the first stacked transistor and the second stacked transistor. The airgap spacer may reduce respective parasitic capacitances that exist between the conductive contact and the first and second stacked transistors. For example, the airgap spacer may relatively reduce capacitance between the deep via and the respective source/drain regions and gates of the first stacked transistor and the second stacked transistor.

### BACKGROUND

The embodiments of the present disclosure relate to fabrication methods and resulting structures for semiconductor devices.

A backside back-end-of-line (BEOL) network, such as a backside power distribution network (BSPDN), may include signal wires for signal routing and power wires for providing power potential (e.g., VDD, VSS, etc.). The backside BEOL network may allow for the distribution of power wires and signal wires between both the frontside and backside of the semiconductor integrated circuit (IC) device. The backside BEOL network may further allow for the full or partial decoupling of signal routing and/or power routing and/or allows dividing or splitting power wires and/or signal wires between both the frontside and backside of the semiconductor IC device. By incorporating the backside BEOL network, routing congestion may be reduced, which may lead to further semiconductor IC device scaling. For example, semiconductor IC devices that incorporate a backside BEOL network can result in a 30% area reduction and improved current-resistance (IR) drop compared to typical semiconductor IC devices that include solely a frontside BEOL network.

### SUMMARY

In an embodiment of the disclosure, a semiconductor IC device is presented. The semiconductor IC device includes a bottom source/drain region and a top source/drain region stacked above the bottom source/drain region. The semiconductor IC device further includes a conductive contact that includes a deep via and an extension region. The deep via is adjacent to both the bottom source/drain region and the top source/drain region. The extension region laterally protrudes from the deep via. The semiconductor IC device further includes an airgap spacer in contact with the bottom source/drain region, in contact with the top source/drain region, and in contact with the deep via.

In an embodiment of the disclosure, another semiconductor IC device is presented. The semiconductor IC device includes a first stacked transistor comprising a first bottom source/drain region and first top source/drain region stacked above the first bottom source/drain region. The semiconductor IC device further includes a second stacked transistor comprising a second bottom source/drain region and second top source/drain region stacked above the second bottom source/drain region. The semiconductor IC device further includes a conductive contact that includes a deep via and an extension region. The deep via is between the first stacked transistor and the second stacked transistor. The extension region laterally protrudes from the deep via. The semiconductor IC device further includes an airgap spacer around the deep via and in contact with the first bottom source/drain region, in contact with the first top source/drain region, in contact with the second bottom source/drain region, and in contact with the second top source/drain region.

In another embodiment of the disclosure, a method of fabricating a semiconductor IC device is presented. The method includes forming a deep via contact region opening between a first stacked transistor and a second stacked transistor. The method includes forming a via spacer around a perimeter within the deep via contact region opening. The method includes removing the via spacer to form an airgap spacer opening. The method further includes forming a backside interlayer dielectric (ILD) that pinches off within the airgap spacer opening and forms an airgap spacer around the deep via contact region.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1A and FIG. 1B depict respective cross-section views of a semiconductor IC device that includes an airgap spacer around deep via portion, according to one or more embodiments of the disclosure.

FIG. 2A through FIG. 14B depict respective partial top-down structure views and corresponding fabrication stage cross-section views of an illustrative semiconductor IC device that includes one or more airgap spacers around respective deep via portions, according to one or more embodiments of the disclosure.

FIG. 15 depicts a method of fabricating a semiconductor IC device that includes one or more airgap spacers around respective deep via portions, according to one or more embodiments of the disclosure.

### DETAILED DESCRIPTION

The present disclosure relates to fabrication methods and resulting semiconductor IC devices that include one or more airgap spacers around respective deep via portions of a contact. Stacked transistors typically include source/drain regions that are vertically stacked. These regions may connect to a frontside back end of line (BEOL) network or a backside BEOL network. For example, a bottom source/drain region may connect to the frontside BEOL network by a top-to-bottom contact and a top source/drain region may connect to the backside BEOL network by a bottom-to-top contact. In typical semiconductor IC devices, there is relatively high parasitic capacitance between these contacts and the source/drain regions and between the contacts and one or more conductive gates that are associated with the source/drain regions.

The embodiments of the present disclosure recognize the potential benefits of semiconductor IC device fabrication techniques that provide for the reduction of such parasitic capacitances. To achieve these and potential other benefits, a semiconductor IC device is presented that includes one or more airgap spacers around respective deep via portions of a contact which reduces the parasitic capacitance between at least the respective deep via portions and the source/drain regions and/or the one or more conductive gates that are associated with the source/drain regions.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating semiconductor IC device, such as a processor, FPGA, memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

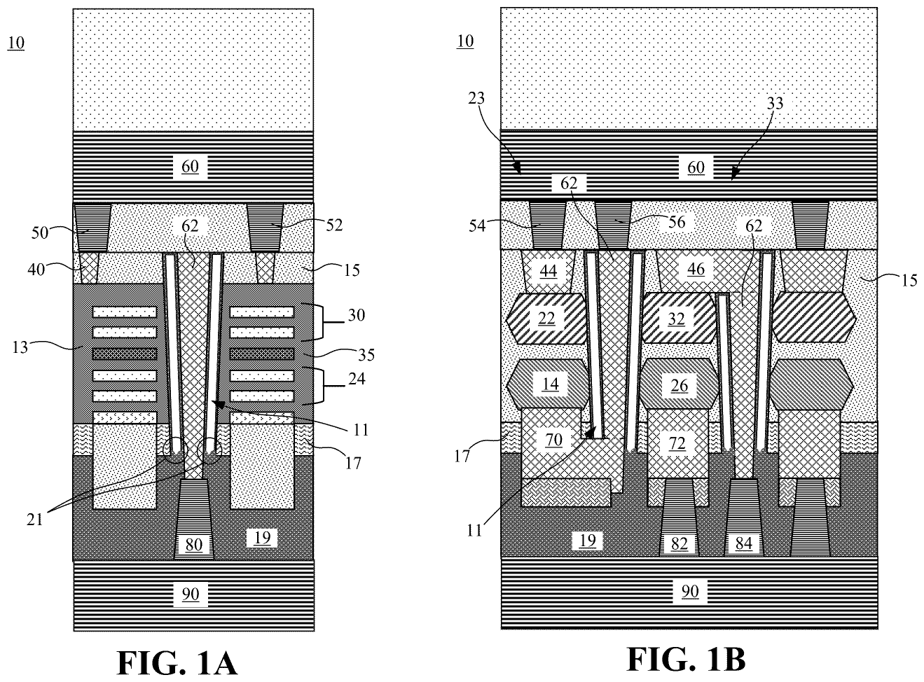

FIG. 1A and FIG. 1B depict respective cross-section views of a semiconductor IC device 10 that includes an airgap spacer 11 around deep via 62 of a respective contact, according to one or more embodiments of the disclosure.

In an embodiment of the disclosure, the semiconductor IC device 10 includes a bottom source/drain region 14 and a top source/drain region 22 stacked above the bottom source/drain region 14. The semiconductor IC device 10 further includes a conductive contact that includes the deep via 62 that is adjacent to both the bottom source/drain region 14 and the top source/drain region 22 and an extension region that laterally protrudes from the deep via 62. In examples, the extension region may be a backside contact 70, as depicted, or a frontside contact 46. The semiconductor IC device 10 further includes an airgap spacer 11 in contact with the bottom source/drain region 14, in contact with the top source/drain region 22, and in contact with the deep via 62.

The airgap spacers 11 may reduce the parasitic capacitance between at least the respective deep via 62 and the bottom source/drain region 14 and between at least the respective deep via 62 and the top source/drain region 22.

In an example, the semiconductor IC device 10 further includes a conductive gate 13 that controls respective charge carrier flow to/from both the bottom source/drain region 14 and the top source/drain region 22. The deep via 62 is further adjacent to the conductive gate 13, and the airgap spacer 11 is further in contact with the conductive gate 13. The airgap spacers 11 may reduce the parasitic capacitance between at least the respective deep via 62 and the conductive gate 13.

In an example, a top surface of the airgap spacer 11 is above a top surface of the top source/drain region 22 and a top surface of the conductive gate 13. For example, the top surface of the airgap spacer 11 may be coplanar with a top surface of the interlayer dielectric (ILD) 15, the top surface of the deep via 62, or the like.

In an example, a bottom surface of the airgap spacer 11 is below a bottom surface of the bottom source/drain region 14 and a bottom surface of the conductive gate 13. For example, the bottom surface of the airgap spacer 11 may inset within a shallow trench isolation (STI) region 17 that is located underneath the conductive gate 13. In this manner, when combined with the above, the airgap spacer 11 may extend from above the FEOL section to below the FEOL section in which the transistors associated with the bottom source/drain region 14 and top source/drain region 22. The geometry of the airgap spacer 11 may allow for robust relative parasitic capacitance reduction.

In an example, the semiconductor IC device 10 further includes a frontside gate contact 40 connected to the conductive gate 13 and a frontside back end of line (BEOL) network 60 connected to the frontside gate contact 40 by a gate interconnect 50. The frontside BEOL network 60 may include conductive frontside wires where at least 90% of conductive frontside wires (e.g., closest to the transistor(s)) are signal routing wires.

In an example, a top surface of the airgap spacer 11 is substantially coplanar with a bottom surface of frontside gate contact 40. For example, the top surface of the airgap spacer 11 may be coplanar with a top surface of the interlayer dielectric (ILD) 15, the top surface of the deep via 62, or the like.

In an example, the semiconductor IC device 10 further includes a shallow trench isolation (STI) region 17 underneath the conductive gate 13 and below and adjacent to the bottom source/drain region 14. In the example, the deep via 62 is further adjacent to the STI region 17 and the airgap spacer 11 is further in contact with the STI region 17. The STI region 17 may establish the lower boundary of the airgap spacer 11. For example, the bottom surface of the airgap spacer 11 may inset within the STI region 17.

In an example, the semiconductor IC device 10 further includes a backside interlayer dielectric (ILD) 19 underneath the STI region 17 and in contact with the deep via 62. A pinch-off region 21 of the backside ILD 19 defines a bottom surface of the airgap spacer 11 which may inset within the STI region 17. In this manner, the bottom surface of the airgap spacer 11 may be below or underneath the FEOL section and may allow for robust relative parasitic capacitance reduction.

In an example, the pinch off region 21 of the backside ILD 19 is between a bottom surface of the STI region 17 and a top surface of the STI region 17. For example, the bottom surface of the airgap spacer 11 which may inset within the STI region 17 and may allow for robust relative parasitic capacitance reduction.

In an example, the extension region is directly coupled against a top surface of the top source/drain region 22. In this way, the conductive contact is a bottom-to-top contact which may connect the top source/drain region 22 to a backside (BEOL) network 90. In this example, at least 90% of the backside conductive wires that are in metal levels closest to the transistor(s) are power routing wires.

In an example, the extension region is directly coupled against a bottom surface of the bottom source/drain region 14. In this way, the conductive contact is a top-to-bottom contact which may connect the bottom source/drain region 14 to the frontside BEOL network 60.

In another embodiment of the disclosure, another instance of the semiconductor IC device 10 is presented. The semiconductor IC device 10 includes a first stacked transistor 23 that includes a first bottom source/drain region 14 and first top source/drain region 22 stacked above the first bottom source/drain region 14. The semiconductor IC device 10 further includes a second stacked transistor that includes a second bottom source/drain region 26 and second top source/drain region 32 stacked above the second bottom source/drain region 26. A conductive contact comprising a deep via 62 is between the first stacked transistor 23 and the second stacked transistor 33 and an extension region that laterally protrudes from the deep via 62. In examples, the extension region may be a backside contact 70, as depicted, or a frontside contact 46. The semiconductor IC device 10 further includes an airgap spacer 11 around the deep via 62 and in contact with the first bottom source/drain region 14, in contact with the first top source/drain region 22, in contact with the second bottom source/drain region 26, and in contact with the second top source/drain region 32.

The airgap spacer 11 may reduce the parasitic capacitance between the first stacked transistor 23 and the second stacked transistor 33. For example, the airgap spacer 11 may reduce the parasitic capacitance between the at least the respective deep via 62 and the first bottom source/drain region 14, between at least the respective deep via 62 and the first top source/drain region 22, between the at least the respective deep via 62 and the second bottom source/drain region 26, and between at least the respective deep via 62 and the second top source/drain region 32.

In an example, the semiconductor IC device 10 further includes a first conductive gate 13 that controls respective charge carrier flow to/from both the first bottom source/drain region 14 and the first top source/drain region 22. The semiconductor IC device 10 further includes a second conductive gate 35 that controls respective charge carrier flow to/from both the second bottom source/drain region 26 and the second top source/drain region 32. The deep via 62 and the airgap spacer 11 are further between the first conductive gate 13 and the second conductive gate 35. As such, the airgap spacer 11 may reduce the parasitic capacitance between at least the respective deep via 62 and the first conductive gate 13 and the second conductive gate 35.

In an example, a top surface of the airgap spacer 11 is above a top surface of the first and second top source/drain regions 22, 32 and a top surface of the first and second conductive gates 13, 35. For example, the top surface of the airgap spacer 11 may be coplanar with a top surface of the interlayer dielectric (ILD) 15, the top surface of the deep via 62, or the like.

In an example, a bottom surface of the airgap spacer 11 is below a bottom surface of the first and second bottom source/drain regions 14, 26 and a bottom surface of the first and second conductive gates 13, 35. For example, the bottom surface of the airgap spacer 11 may inset within a shallow trench isolation (STI) region 17 that is located underneath the conductive gate 13. In this manner, when combined with the above, the airgap spacer 11 may extend from above the FEOL section to below the FEOL section in which the first stacked transistor 23 and the second stacked transistor 33 are formed. This geometry of the airgap spacer 11 may allow for robust relative parasitic capacitance reduction.

In an example, the semiconductor IC device 10 further includes a first frontside gate contact 40 connected to the first conductive gate 13 and a second frontside gate contact 42 connected to the second conductive gate 35. The semiconductor IC device 10 further includes the frontside BEOL network 60 connected to the first frontside gate contact 40 by a first gate interconnect 50 and connected to the second frontside gate contact 42 by a second gate interconnect 52.

In an example, a top surface of the airgap spacer 11 is substantially coplanar with a bottom surface of the first and second gate interconnects 40, 42. The frontside BEOL network 60 may include conductive frontside wires where at least 90% of conductive frontside wires (e.g., furthest from the first stacked transistor 23 and the second stacked transistor 33 are signal routing wires and the remainder conductive frontside wires which are usually present in metal levels closest to the transistor, can be used as power routing wires.

In an example, the semiconductor IC device 10 further includes the STI region 17 underneath the first and second conductive gates 13, 35 and below and between the first and second bottom source/drain regions 14, 26. In this example, a bottom surface of the deep via 62 is below a bottom surface of the STI region and the airgap spacer 11 is further in contact with the STI region 17.

In an example, the semiconductor IC device 10 further includes the backside ILD 19 underneath the STI region 17 and in contact with the deep via 62 and the pinch-off region 21 defines a bottom surface of the airgap spacer 11. In this manner, the bottom surface of the airgap spacer 11 may be below or underneath the FEOL section and may allow for robust relative parasitic capacitance reduction between the first stacked transistor 23 and the second stacked transistor 33.

In another embodiment of the present disclosures, a method of fabricating the semiconductor IC device 10 is presented. The method includes forming a deep via 62 opening between a first stacked transistor 23 and a second stacked transistor 33. The method includes forming a via spacer around a perimeter within the deep via 62 opening. The method further includes removing the via spacer to form an airgap spacer opening. The method further includes forming the backside ILD 19 that pinches off within the airgap spacer opening and forms the airgap spacer 11 around the deep via 62.

The airgap spacer 11 may reduce the parasitic capacitance between the first stacked transistor 23 and the second stacked transistor 33.

The semiconductor IC device 100 of FIG. 1A and FIG. 1B further depicts channels 12 that may be connected to the bottom source/drain region 14, channels 20 that may be connected to top source/drain region 22, channels 24 that may be connected to the bottom source/drain region 26, and channels 30 that may be connected to source/drain region 32.

The semiconductor IC device 100 of FIG. 1A and FIG. 1B further depicts a frontside contact 44 that may be connected to the source/drain region 22 and a frontside contact 46 that may be connected to the source/drain region 32 and connected to deep via 62. Respective one or more wires within frontside BEOL network 60 may be connected to the frontside contact 44 and to the frontside contact 46.

The semiconductor IC device 100 of FIG. 1A and FIG. 1B further depicts a backside contact 80 that may be connected to a deep via 62, a backside contact 70 that may be connected to a deep via 62 and to the source/drain region 14, and a backside contact 72 that may be connected to the source/drain region 26. Respective one or more wires within backside BEOL network 90 may be connected to the backside contacts 80, 82, 84. In this example, at least 90% of the backside conductive wires that are in metal levels closest to the first stacked transistor 23 and the second stacked transistor 33 are power routing wires (e.g., wires that carry a VDD, VSS potential).

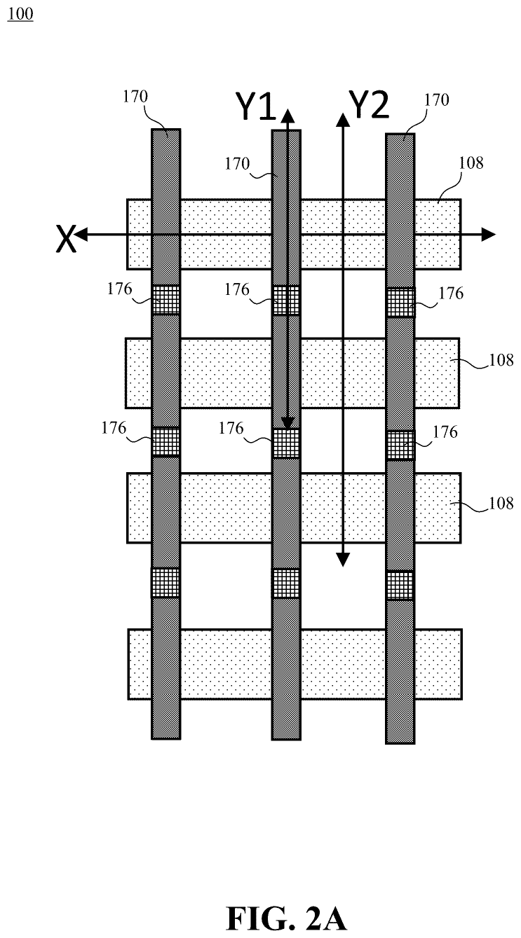

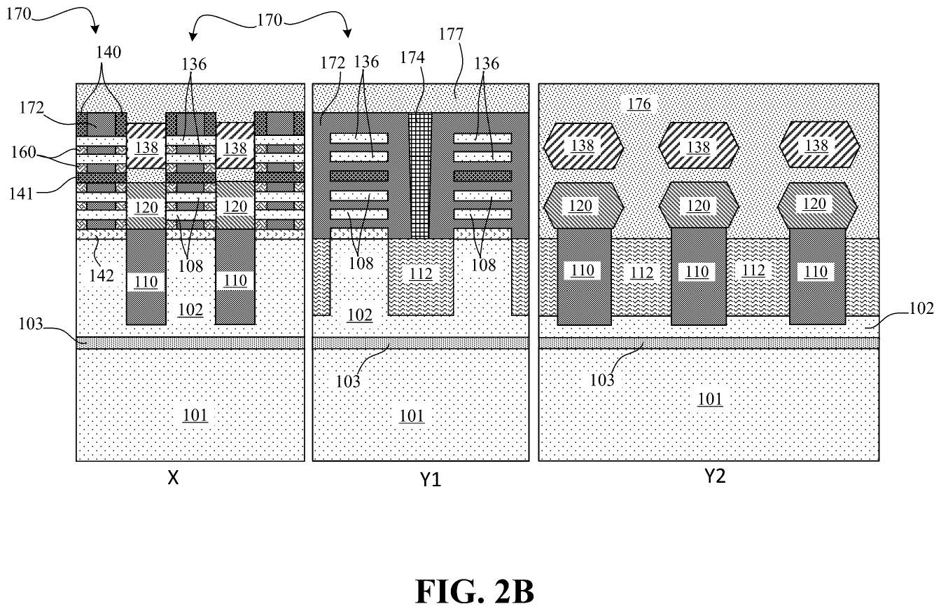

FIG. 2A and FIG. 2B depict respective partial top-down structure views and corresponding fabrication stage cross-section views of an illustrative semiconductor IC device 100 that is to include one or more airgap spacers around respective deep via portions of a contact, according to one or more embodiments of the disclosure.

FIG. 2A depicts active semiconductor nanolayers 108 and replacement gate structures 170 that include one or more gate cut regions 176 therein. FIG. 2A depicts various cross-sectional planes. Cross-sectional plane X is along an active semiconductor nanolayer 108 and across various replacement gate structures 170. Cross-sectional plane Y1 is along a replacement gate structure 170 across adjacent active semiconductor nanolayers 108. Cross-sectional plane Y2 is parallel to cross-sectional plane Y1 in between adjacent replacement gate structures 170.

FIG. 2A depicts fabrication stage cross-section views of illustrative semiconductor IC device 100. At the present fabrication stage, semiconductor IC device 100 may include a lower substrate 101, an etch stop layer 103, an upper substrate 102, shallow trench isolation regions 112, backside contact placeholders 110, bottom isolation layers 142, bottom active semiconductor nanolayers 108, bottom source/drain regions 120, top source/drain regions 138, middle isolation layers 141, top active semiconductor nanolayers 136, gate spacers 140, inners spacers 160, replacement gate structures 170 which may include one or more conductive gate 172 material(s), gate cut regions 174, and/or interlayer dielectric (ILD) 177.

The illustrated semiconductor IC device 100 may be formed by stacked transistor semiconductor IC device fabrication techniques the description of which are not included herein. These techniques to manufacture of semiconductor devices may be known or later developed and may not be directed toward the claimed embodiments. As such, for the sake of brevity, these techniques are not described in detail herein.

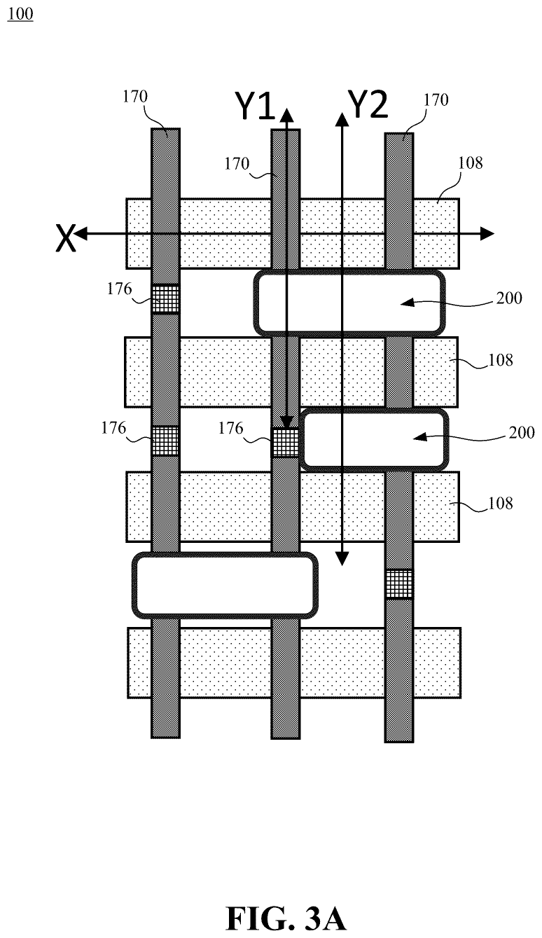

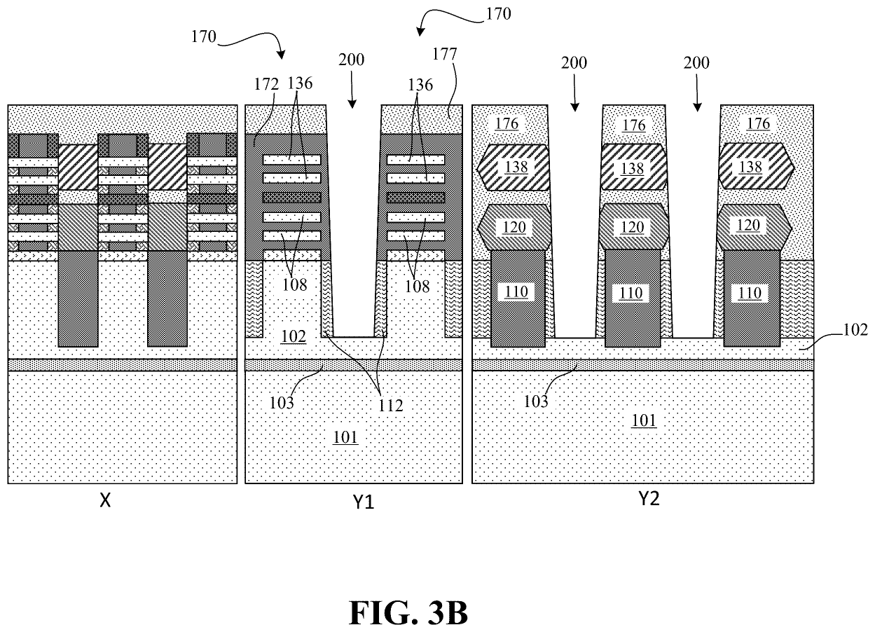

FIG. 3A and FIG. 3B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, deep via trenches 200 may be formed.

The deep via trenches 200 may be formed by depositing and patterning a mask (not shown). For example, the mask may be formed and patterned to create an opening therein. The mask may consist of a nitride material, such as, but not necessarily limited to, silicon nitride (SiN) or titanium nitride (TiN), a low temperature oxide, such as an organic planarization layer (OPL), or the like. The mask can be deposited using deposition techniques including, but not necessarily limited to, chemical vapor deposition (CVD), plasma enhanced CVD (PECVD), radio-frequency CVD (RFCVD), physical vapor deposition (PVD), atomic layer deposition (ALD), molecular layer deposition (MLD), molecular beam deposition (MBD), pulsed laser deposition (PLD), liquid source misted chemical deposition (LSMCD), or the like.

Subsequently, a photoresist (not shown) may be formed over the mask. The photoresist may include a positive-tone photoresist composition, a negative-tone photoresist composition, or a hybrid-tone photoresist composition. A layer of photoresist material may be formed by a deposition process such as, for example, spin-on coating. The deposited photoresist may be subjected to a pattern of irradiation, and the exposed photoresist material is developed utilizing resist developer. The pattern provided by the patterned photoresist material is transferred through the mask to form the deep via trenches 200.

An etch may pattern or transfer the openings into the mask. The deep via trenches 200 may be further formed by subjecting the semiconductor IC device 100 to a etch stage, to remove respective portions of the ILD 177, replacement gate structures 170, upper source/drain regions 138, lower source/drain regions 122, and STI regions 112.

The deep via trenches 200 may remove and expose at least a portion of an associated sidewall of respective upper source/drain regions 138 and respective lower source/drain regions 122. The exposed surface of the upper source/drain regions 138 and the lower source/drain regions 122 by the deep via trenches 200 may be referred to as a cut surface, respectively. The deep via trenches 200 may further remove and expose respective sidewalls of the ILD 177, replacement gate structure 170, and STI region 112.

The etch may be timed or otherwise controlled to remove the materials the ILD 177, replacement gate structures 170, upper source/drain regions 138, lower source/drain regions 122, and STI regions 112. In an example, the etch may utilize the top surface of the upper substrate 102 as an etch stop.

The deep via trenches 200 may be located between adjacent vertical stacks of bottom active semiconductor nanolayers 108 and top active semiconductor nanolayers 136, may further be located between adjacent top source/drain regions 128, and may further be located between adjacent replacement gate structures 170.

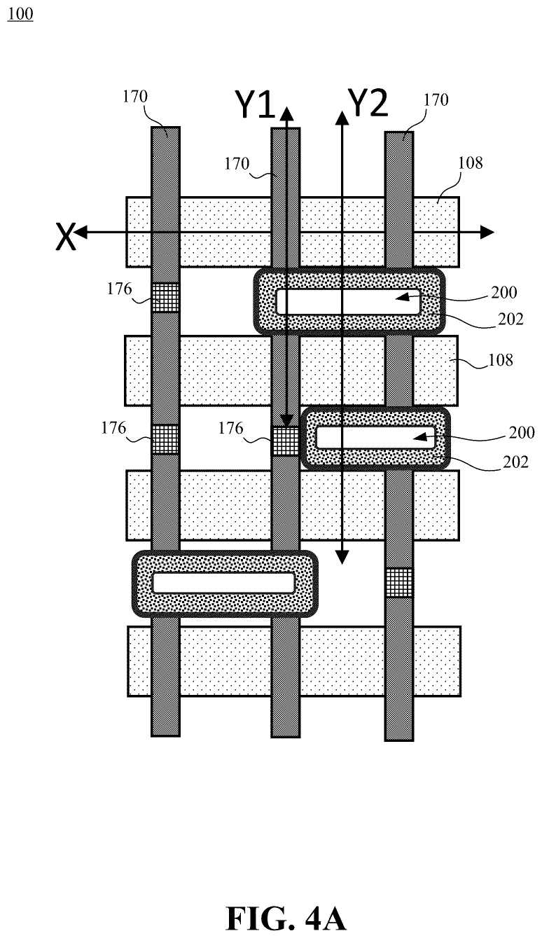

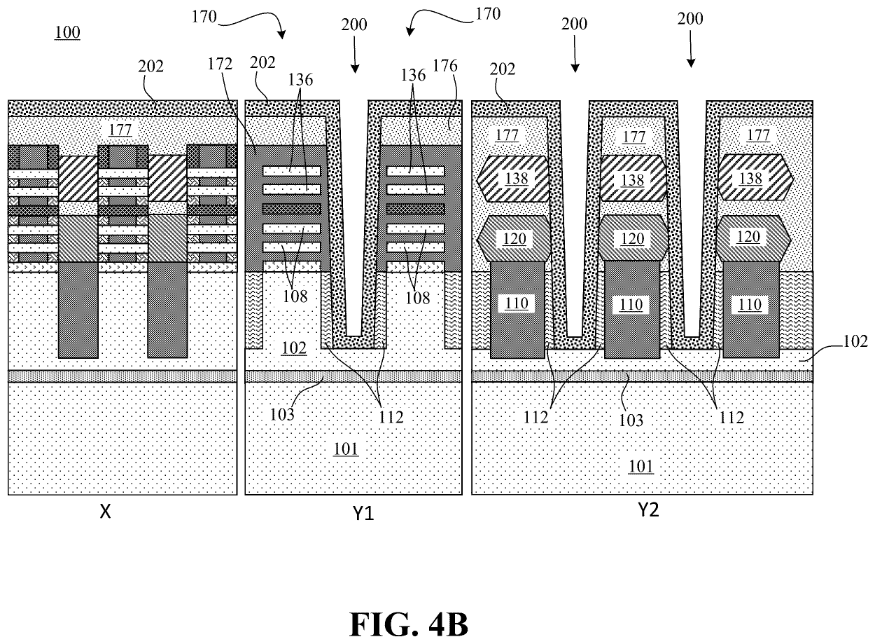

FIG. 4A and FIG. 4B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, a deep via spacer 202 layer may be formed.

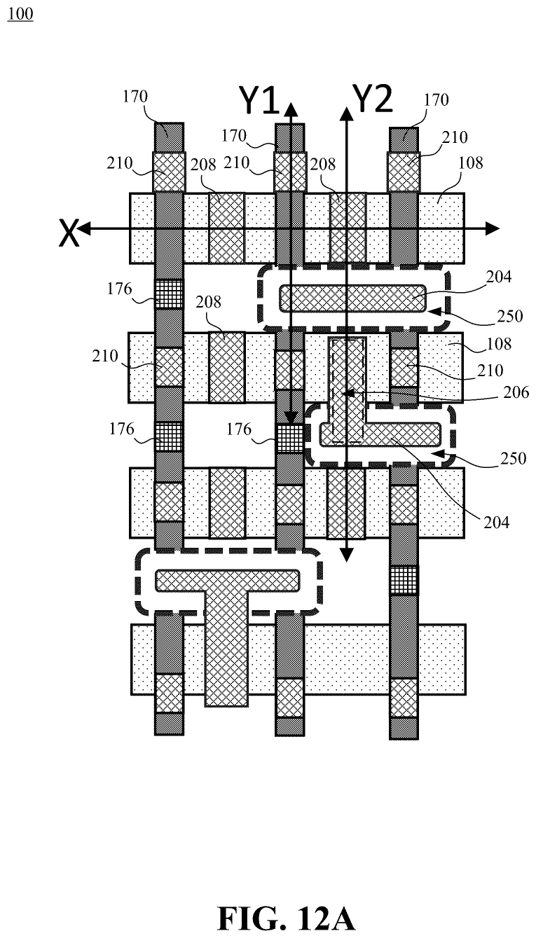

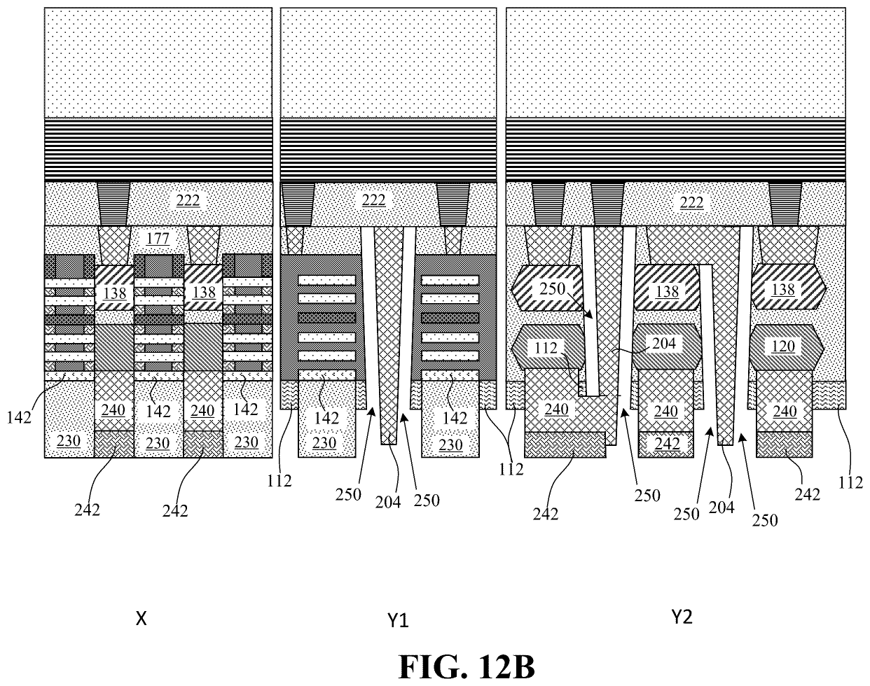

The deep via spacer 202 layer may be formed by depositing a blanket dielectric material over the ILD 177 and within the deep via trenches 200. The deep via spacer 202 layer can be any suitable material, such as, for example, porous silicates, carbon doped oxides, silicon dioxides, silicon nitrides, silicon oxynitrides, or other dielectric materials that has etch selectivity with respect to ILD 177, the one or more conductive gate 172 material(s), frontside contact ILD 222 (illustratively depicted in FIG. 12B), bottom source/drain region(s) 120, top source/drain region(s) 138, backside ILD 230 (illustratively depicted in FIG. 12B), etc. In an illustrative example, the material of the deep via spacer 202 layer may be SiO₂, SiN, SiOCN, SiOC, SiC, SiBCN, AlOₓ, or the like. Any known manner of forming the deep via spacer 202 layer can be utilized. The deep via spacer 202 layer can be formed using, for example, CVD, PECVD, ALD, flowable CVD, spin-on dielectrics, PVD, or the like.

In an example, the deep via spacer 202 layer may be formed to a thickness so that deep via trenches 200 remain. Subsequently, a planarization process, such as a CMP, may be performed to remove excess deep via spacer 202 layer which may form a respective deep via spacer 202 within a deep via trench 200. The CMP may create a substantially planar or substantially horizontal top surface for the semiconductor IC device 100. In other words, the respective top surfaces of the ILD 177 and of the deep via spacers 202 may be substantially coplanar and/or substantially horizontal.

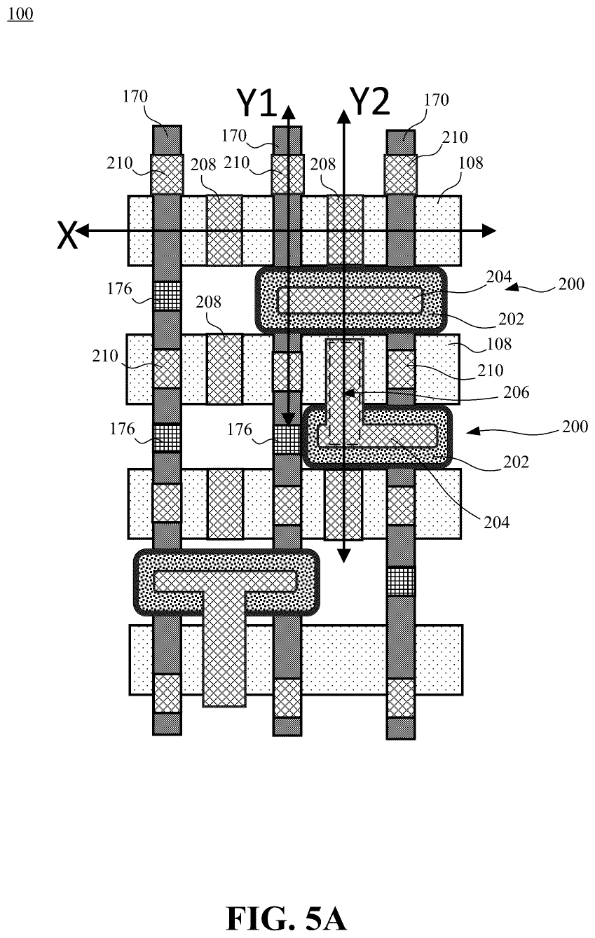

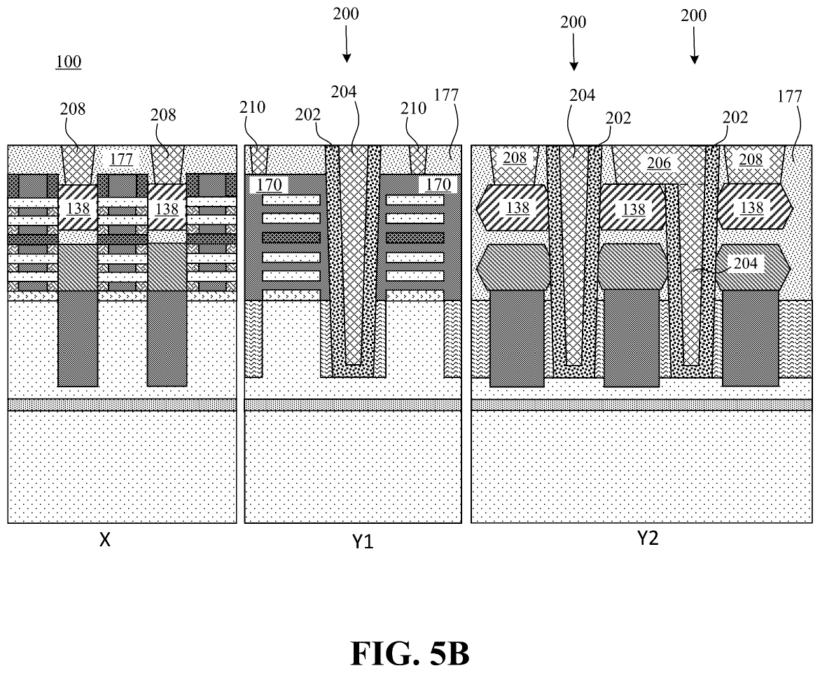

FIG. 5A and FIG. 5B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, frontside contacts 206, 208, 210 and deep vias 204 may be formed.

Frontside contacts 206, 208, 210 may be formed may be formed by patterning respective frontside contact openings within the ILD 177 from the frontside (i.e., from above the semiconductor IC device 100, as depicted, downward to respective structures thereof). The frontside contacts 205, 208, 210 may be in direct or indirect physical and electrical contact and/or may physically meld with respective material(s) of one or more regions of the semiconductor IC device 100. For example, a frontside contact 206 opening may expose a portion of a top source/drain region 138, a frontside contact 208 opening within ILD 177 may expose a portion of a top source/drain region 138, and a frontside contact 210 opening within ILD 177 may expose a portion of a replacement gate structure 170.

The frontside contact openings may be formed by the same or shared lithography and etch process(es), or sequential lithography and etch processes. In such process(es), a mask may be applied and patterned. An opening in the patterned mask may expose the portion of the underlying ILD 177 to be removed while other protected portions of semiconductor IC device 100 thereunder may be protected and retained. In such process(es), the etching processes can have etching parameters that can be tuned, such as etchants used, etching temperature, etching solution concentration, etching pressure, source power, RF bias voltage, RF bias power, etchant flow rate, to promote desired material removal and desired material retention. For clarity, in a particular region that is associated with a contact 205, a frontside contact opening may overlap or otherwise intersect with or join a deep via trench 200.

The frontside contacts 206, 208, 210 may be further formed by depositing conductive material such as metal into the respective frontside contact openings. Simultaneously, deep vias 204 may be formed by depositing conductive material such as metal into the respective frontside deep via trenches 200.

In an example, the frontside contacts 206, 208, 210 and deep vias 204 may be formed by depositing a liner, such as Ni, NiPt or Ti, etc. into the respective openings, depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and conductive fill. Subsequently, the respective top surfaces of the frontside contacts 206, 208, 210 and deep vias 204 and the ILD 177 may be coplanar. In embodiments, the frontside contacts 206, 208, 210 and deep vias 204 are fabricated in MOL fabrication operations and may be illustrations of MOL frontside contacts and/or MOL deep via interconnects, respectively.

For clarity, in the region that is associated with a contact 205, the deposition of conductive material(s) within the frontside contact opening which is overlapped or otherwise with the deep via trench 200 results in the formation of contact 205 that includes a frontside contact 206 and a deep via 204. As the deep via 204 and the frontside contact 206 associated with the same contact 205 may be fabrication from the same conductive material deposition processes, there may be no contact or interfacial impedance and/or resistance between the deep via 204 and the frontside contact 206 of the particular contact 205. A boundary between the deep via 204 and the frontside contact 206 may be a substantially horizontal plane that is coplanar with a top surface of a top source/drain region 138 to which the associated frontside contact 206 is connected.

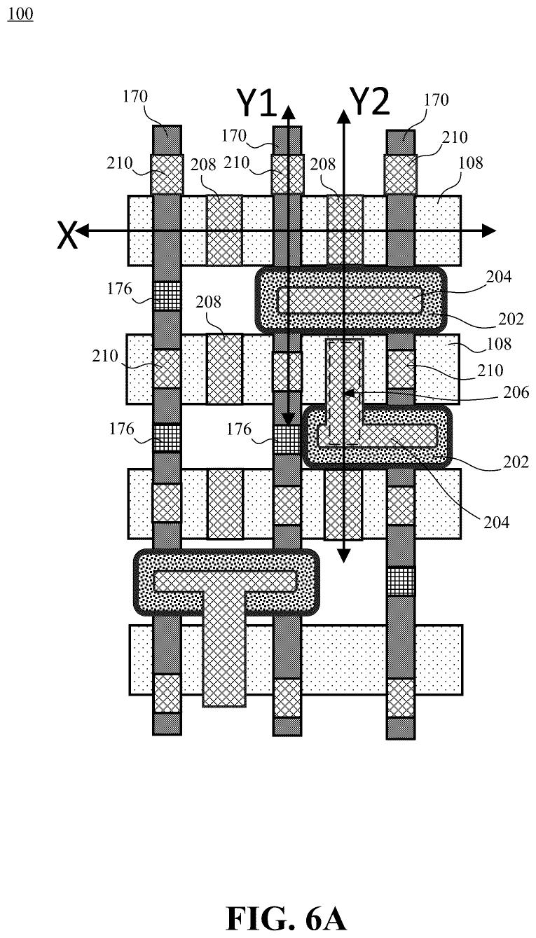

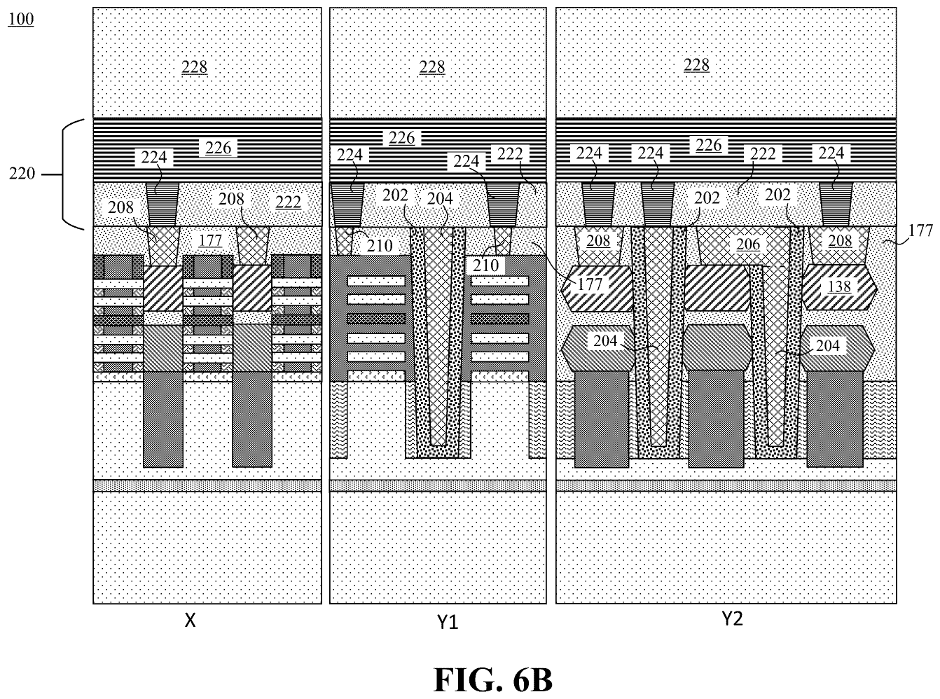

FIG. 6A and FIG. 6B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, a frontside BEOL network 226 may be formed and a carrier wafer 228 may be bonded thereto.

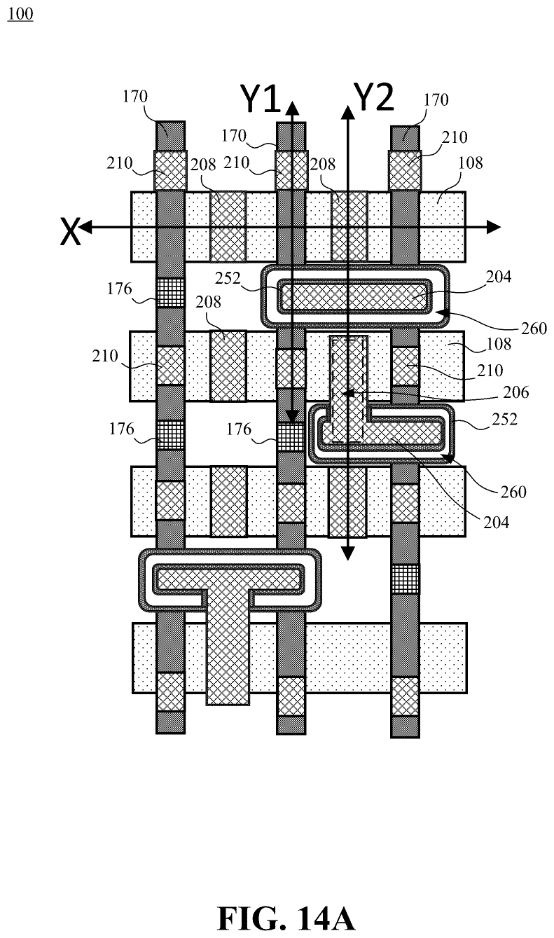

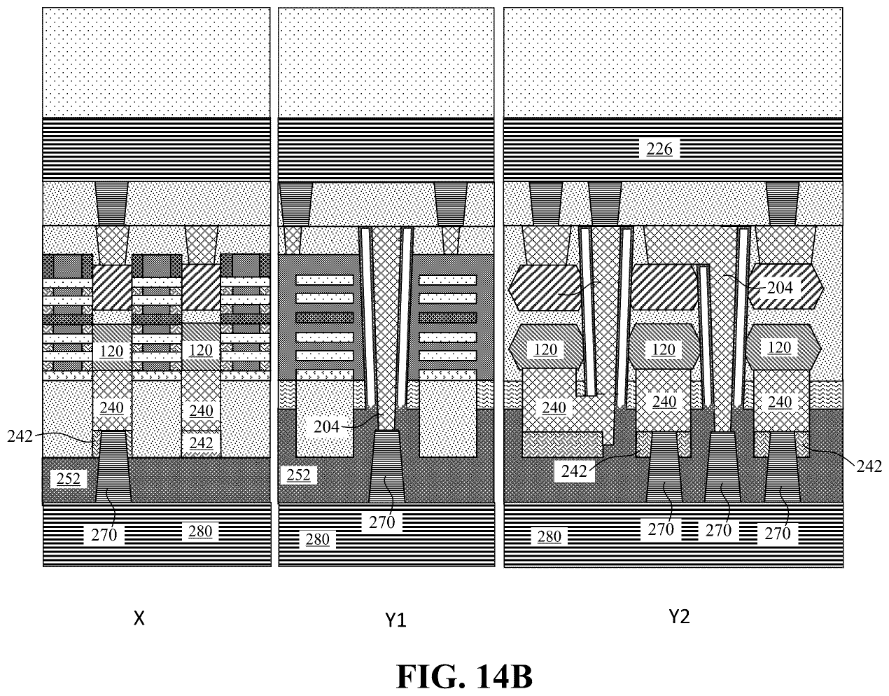

BEOL section is the portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL section, contacts (pads), interconnect wires, vias and dielectric structures maybe formed. For modern IC processes, more than one metal layers may be added in the BEOL. In the present example, there are multiple BEOL networks, each on opposites sides of the semiconductor IC device 100. First, a frontside BEOL network 226 is formed on the frontside of the semiconductor device 100. Subsequently, a backside BEOL network 280, as depicted in FIG. 14B is formed.

In the depicted example, the frontside BEOL network 226 may be formed over the ILD 177, upon the frontside contacts 206, 208, 210, and deep vias 204. Respective wires within the frontside BEOL network 226 may be electrically connected to the one or more top S/D regions 138, one or more replacement gate structure(s) 170, and one or more deep vias 204. For example, a respective wire within the wiring levels 220 of the frontside BEOL network 226 may be electrically connected to the top S/D region 138 by frontside contact 208 and a respective frontside interconnect 224. Similarly, a respective wire within the wiring levels 220 of the frontside BEOL network 226 may be electrically connected to one or more replacement gate structure(s) 170 by frontside contact 210 and a respective frontside interconnect 224. Similarly, a respective wire within the wiring levels 220 of the frontside BEOL network 226 may be electrically connected to deep vias 204 by a respective frontside interconnect 224.

The frontside BEOL network 226 may be located directly on the frontside surface of the MOL section. The frontside BEOL network 226 can include one or more interconnect dielectric material layers (such as ILD 222 which may include one of the dielectric materials mentioned above for the ILD 194) and contains frontside conductive wires or interconnects (the conductive wires or interconnects can be composed of any electrically conductive metal or electrically conductive metal alloy) embedded therein. In some embodiments, the frontside conductive wires within the frontside BEOL network 226 may be composed of Cu. The frontside BEOL network 226 can include “x” numbers of frontside metal levels, wherein “x” is an integer starting from 1. The frontside BEOL network 226 may further contain conductive pads that are connected to one or more of the conductive wires and may be used to connect the semiconductor IC device 100 to an external and/or higher-level structure, such as a chip carrier, motherboard, or the like.

Subsequently, a carrier wafer 228 that may consist of one of the semiconductor materials mentioned above for the upper substrate 102 and may be bonded to the frontside BEOL network 226. Carrier wafer 228 may be attached to the semiconductor IC device 100 by a wafer-to-wafer bonding technique.

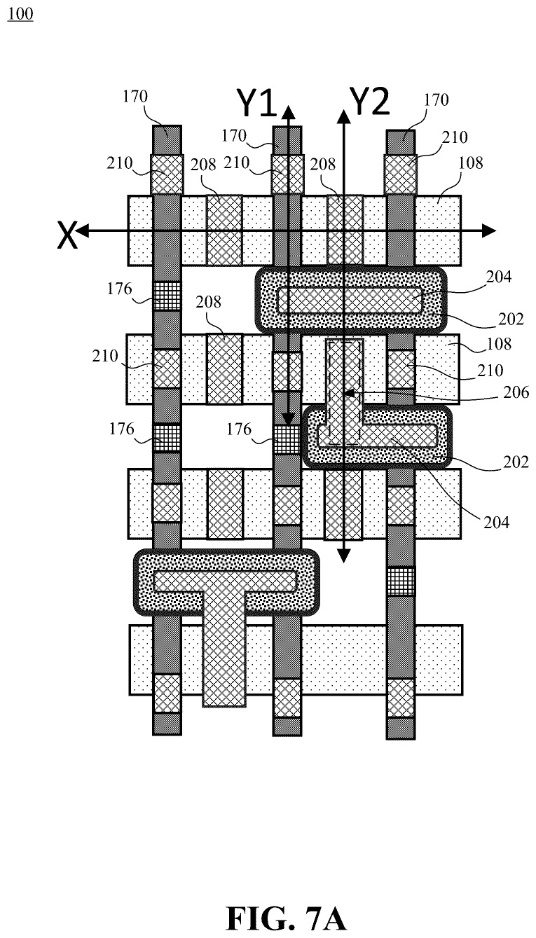

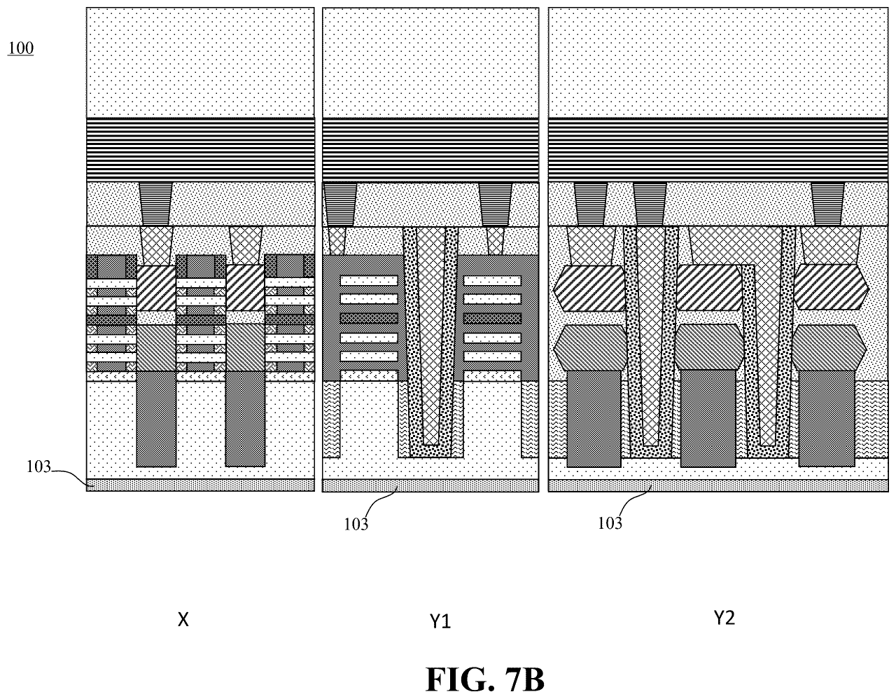

FIG. 7A and FIG. 7B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, the lower substrate 102 may be removed and is therefore not shown in the illustrated figures.

For example, the lower substrate 102 may be removed by flipping the semiconductor IC device 100 (not shown) and removing the lower substrate 102 using any removal technique, such as a combination of wafer grinding, CMP, a dry, and/or a wet etch. In the example depicted, the lower substrate 102 is removed by an etch that utilizes etch stop layer 103 as the etch stop. In this example, removal of the lower substrate 102 exposes the bottom surface of etch stop layer 103.

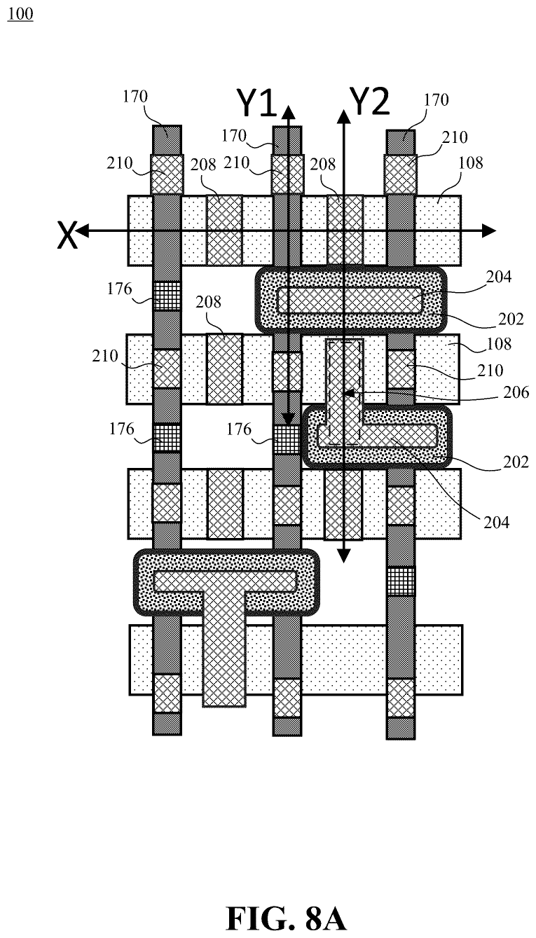

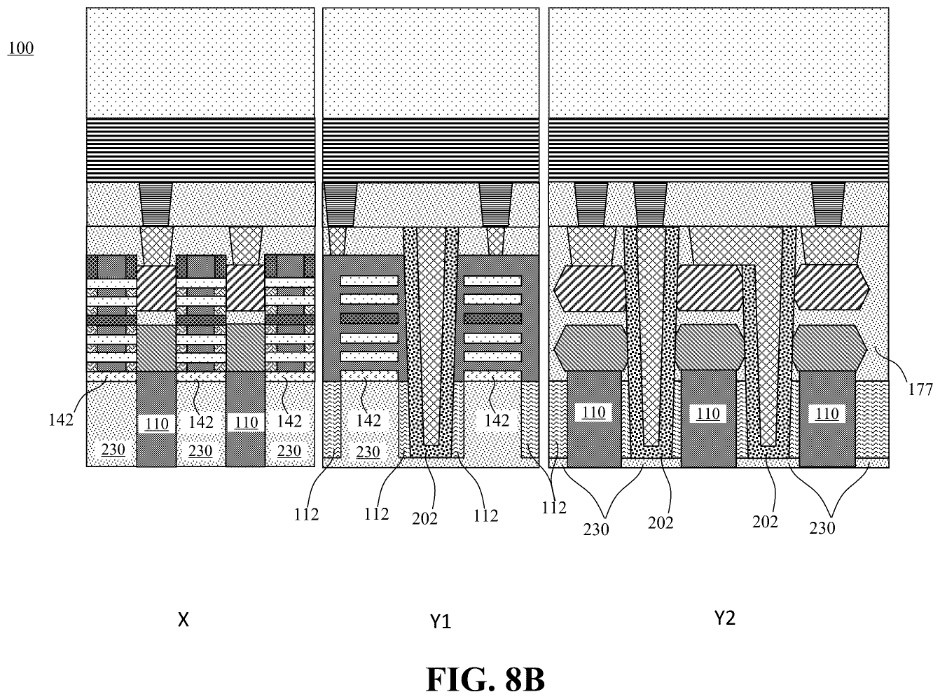

FIG. 8A and FIG. 8B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, the etch stop layer 103 and the upper substrate 104 may be removed and are therefore not shown in the illustrated figures. Further, in the present fabrication stage, backside ILD 230 may be formed.

The etch stop layer 103 may be removed by a selective dry and/or wet etch. Upon removal of the etch stop layer 103, the bottom surface of upper substrate 104 is exposed. The removal of etch stop layer 103 may be selective to the material of upper substrate 104. For example, etch stop layer 103 is removed by an etch that utilizes upper substrate 104 as the etch stop. Subsequently, the upper substrate 104 is removed by an appropriate substrative removal technique, such as an etch, that removes associated portion(s) of the upper substrate 104. The etch may be controlled to remove the material of upper substrate 104 selective to the STI regions 112, selective to the backside contact placeholders 110, and/or selective to the deep via spacers 202, selective to the bottom isolation layers 142, or the like.

The backside ILD 230 may be formed upon the backside of the semiconductor IC device 100. The backside ILD 230 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 230 can be utilized. The backside ILD 230 can be formed using, for example, CVD, PECVD, ALD, flowable CVD, spin-on dielectrics, or PVD.

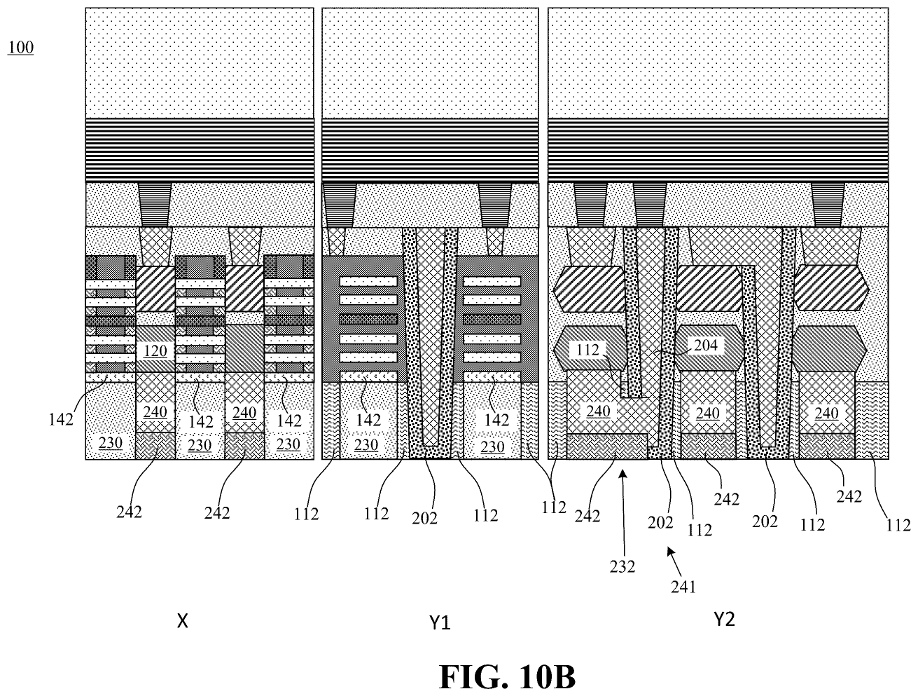

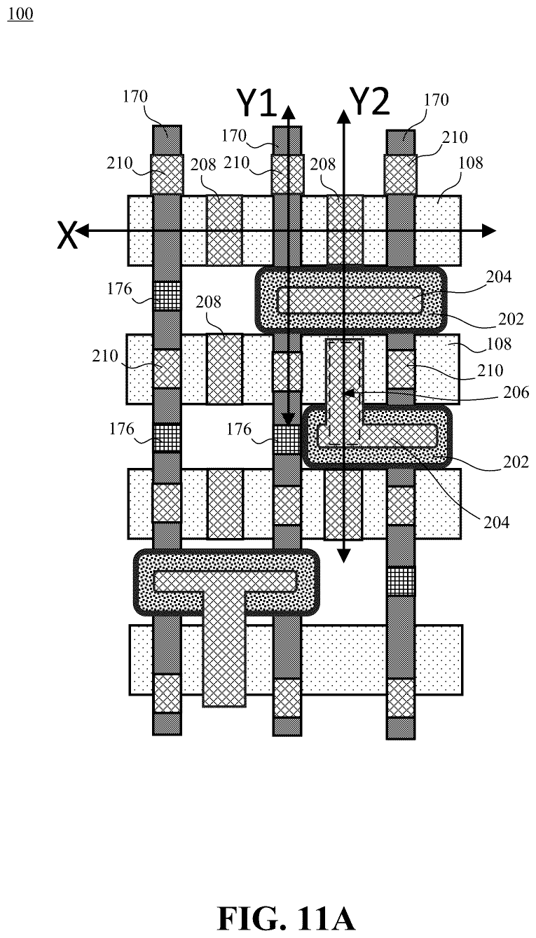

In an example, as depicted, the material of the backside ILD 230 may be the same material as the frontside ILD 177. In alternative examples, the material of the backside ILD 230 may be chosen to achieve a predetermined electrical isolation metric that the dielectric material of frontside ILD 177 could not achieve, if utilized. For example, frontside ILD 177 may be silicon dioxide and the backside ILD 230 may be a low-K dielectric material. Such material selection may provide relatively increased electrical isolation between backside contacts 240, illustratively depicted in FIG. 10B.

A planarization process, such as a CMP process or a mechanical grinding process, may remove excess portions of the backside ILD 230. Therefore, respective bottom surfaces (as depicted) of the backside ILD 230 and the backside contact placeholders 110 may be substantially coplanar and/or substantially horizontal.

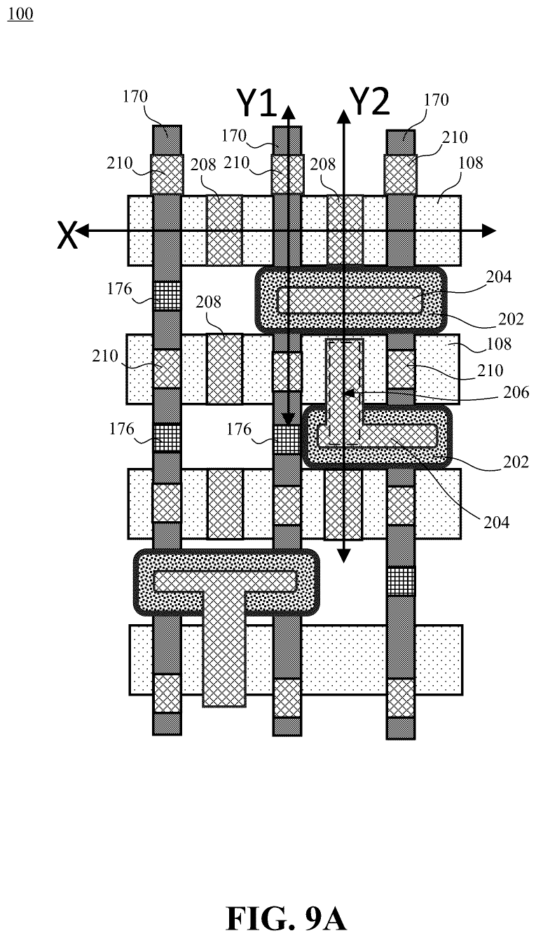

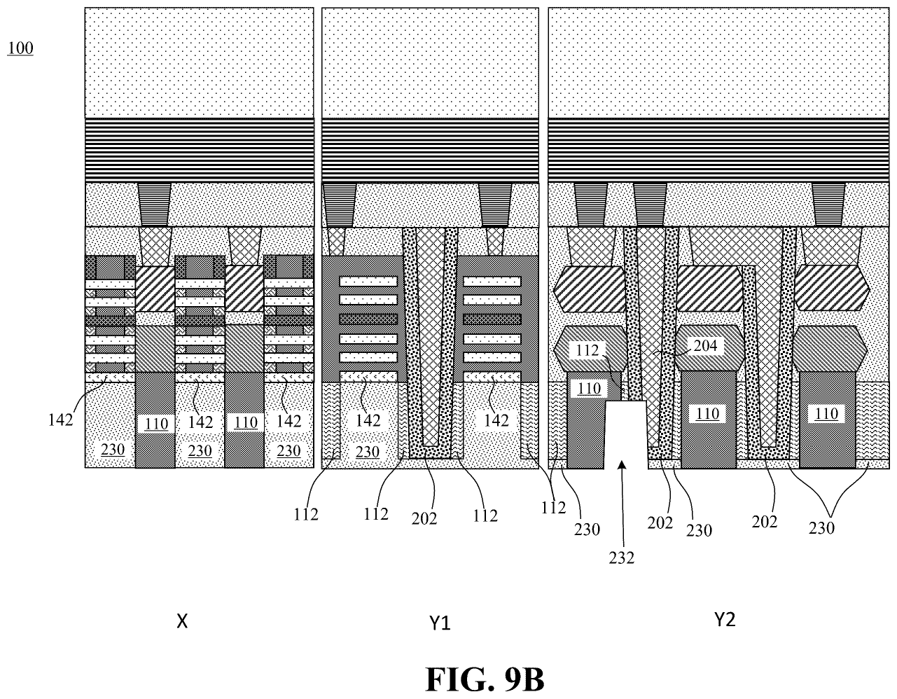

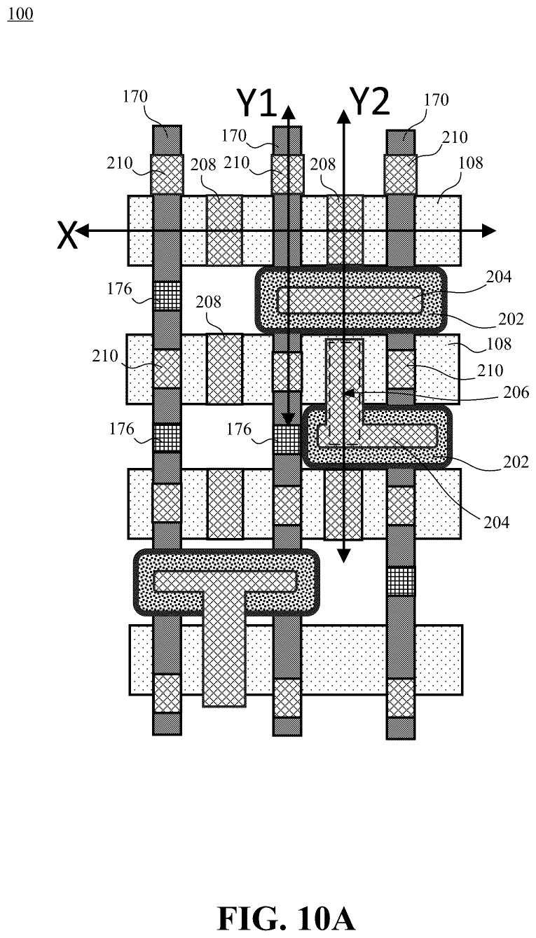

FIG. 9A and FIG. 9B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, extension region opening(s) 232 may be formed.

The extension region opening(s) 232 may be formed by depositing and patterning a mask (not shown). For example, the mask may be formed and patterned to create an opening therein. Subsequently, a photoresist (not shown) may be formed over the mask. The pattern provided by the patterned photoresist material is transferred to the mask to form the extension region opening(s) 232 therein. The extension region opening(s) 232 may be further formed by subjecting the semiconductor IC device 100 to a etch stage that removes respective portions of the backside ILD 230, backside contact placeholder 110, deep via 204, deep via spacer 202, and STI region 112 that are unprotected or otherwise exposed by the extension region opening(s) 232 in the mask. The etch may be timed or otherwise controlled so that a well or depth surface of extension region opening(s) 232 are below the top surface of the STI region(s) 112, as depicted.

FIG. 10A and FIG. 10B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, backside contact placeholder(s) 110 may be removed, backside contact(s) 240 may be formed, and backside contact cap(s) 242 may be formed.

For example, backside contact placeholder(s) 110 may be removed and a backside contact 240 and a backside contact cap 242 may be formed in place of a removed backside contact placeholder 110. Backside contact opening(s) can be formed by the removal of the backside contact placeholder(s) 110 which may expose respective bottom surface(s) of the associated bottom source/drain region 120.

The backside contact opening(s) may be formed by the same or shared lithography and etch process(es), or sequential lithography and etch processes. In such process(es), an etchant may remove the backside contact placeholder(s) 110 selective to the backside ILD 230, STI region(s) 112, bottom isolation layers 142, bottom source/drain region 120. In such process(es), the etching process(es) can have etching parameters that can be tuned, such as etchants used, etching temperature, etching solution concentration, etching pressure, source power, RF bias voltage, RF bias power, etchant flow rate, to promote desired material removal and desired material retention.

Further in the depicted fabrication stage, a backside contact 240 may be formed within a backside contact opening. The backside contact(s) 240 may be formed by depositing conductive material, such as metal, into the respective backside contact opening(s). In this manner, the backside contact 240 is self-aligned to the upper S/D region 192 connected thereto and the lower S/D region backside contact 208 may be self-aligned to the bottom source/drain region 120.

In an example, the backside contact(s) 240 may be formed by depositing a liner, such as Ni, NiPt or Ti, etc. into the backside contact opening(s), depositing an adhesion liner, such as TiN, TaN, etc. upon the liner, and by depositing a conductive fill, such as Al, Ru, W, Co, Cu, etc. upon the adhesion liner.

For clarity, there is a backside contact opening region that is overlapped or otherwise intersects with the extension region opening 232. In this manner, a contact 241 is formed that includes backside contact 240 (i.e., an extension region) and the deep via 204. As the deep via 204 and the backside contact 240 associated with the same contact 241 may be fabricated from the same conductive material deposition processes, there may be no contact or interfacial impedance and/or resistance between the deep via 204 and the backside contact 240 of the particular contact 241.

The backside contact cap 242 may be formed by depositing a blanket dielectric material over the backside ILD 230, upon the STI regions 112, and upon the backside contacts 240. The backside contact cap 242 can be any suitable dielectric material. Any known manner of forming the backside contact cap 242 layer can be utilized. The backside contact cap 242 layer can be formed using, for example, CVD, PECVD, ALD, flowable CVD, spin-on dielectrics, PVD, or the like. Subsequently, a planarization process, such as a CMP, may be performed to remove excess backside contact cap 242 material. The CMP may create a substantially planar or substantially horizontal bottom surface for the semiconductor IC device 100. In other words, the respective bottom surfaces of the backside ILD 230, the STI regions 112, the deep via spacer 202, and backside contact cap 242 may be substantially coplanar and/or substantially horizontal.

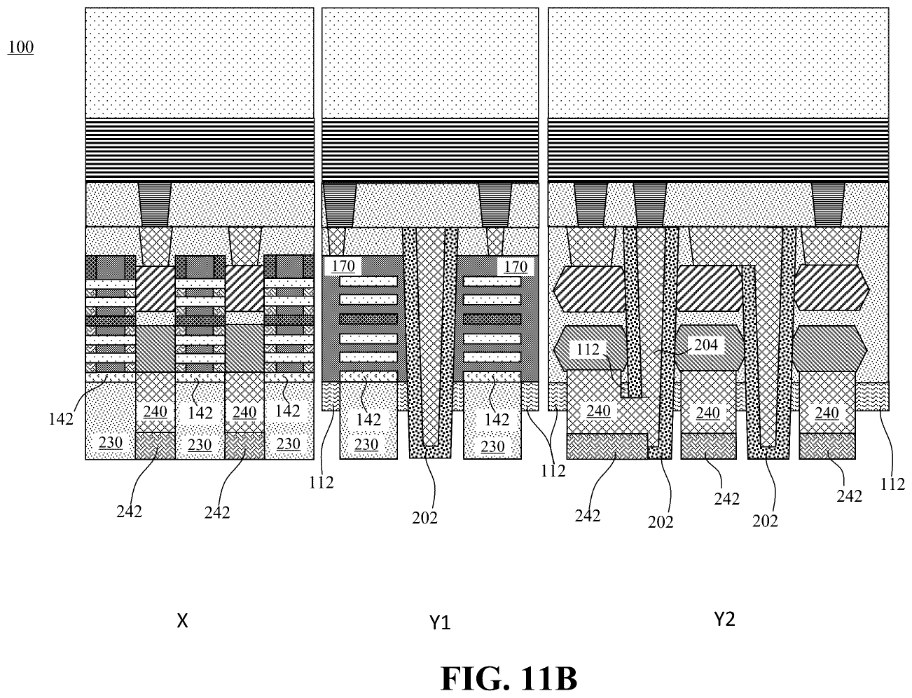

FIG. 11A and FIG. 11B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, the STI regions 112 may be recessed from the backside of the semiconductor IC device 100.

The STI regions 112 may be recessed by etch process(es) in which an etchant may remove lower portions of the STI regions 112 while retaining upper portions of the STI regions 112. The etch may be selective to the backside ILD 230, deep via spacer 202, backside contacts 240, backside contact caps 242. The recessing of the STI regions 112 may generally partially expose respective sidewalls of the deep via spacers 202. The etching process(es) can have etching parameters that can be tuned, such as etchants used, etching temperature, etching solution concentration, etching pressure, source power, RF bias voltage, RF bias power, etchant flow rate, exposure time, to promote desired STI region 112 material removal and desired STI region 112 material retention.

FIG. 12A and FIG. 12B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, the deep via spacers 202 may be removed and are therefore not shown.

The deep via spacers 202 may be removed which may expose the associated deep via 204 and thereby form an airgap spacer opening 250 therearound. The airgap spacer opening 250 may be around the deep via 204, may be against the adjacent replacement gate structures 170, may be against the ILD 177, may be against the frontside contact ILD 222, may be against the STI regions 112, and the like.

The deep via spacers 202 may be removed by etch process(es) whereby an etchant removes the deep via spacers 202 selective to the deep via 204, to the replacement gate structures 170, to the ILD 177, to the frontside contact ILD 222, to the STI regions 112, to the backside ILD 230, to the backside contacts 240, to the backside contact caps 242, the bottom source/drain regions 120, the top source/drain regions 138, the frontside contacts 206, and the like. In such process(es), the etching process(es) can have etching parameters that can be tuned or otherwise controlled to promote deep via spacer 202 removal.

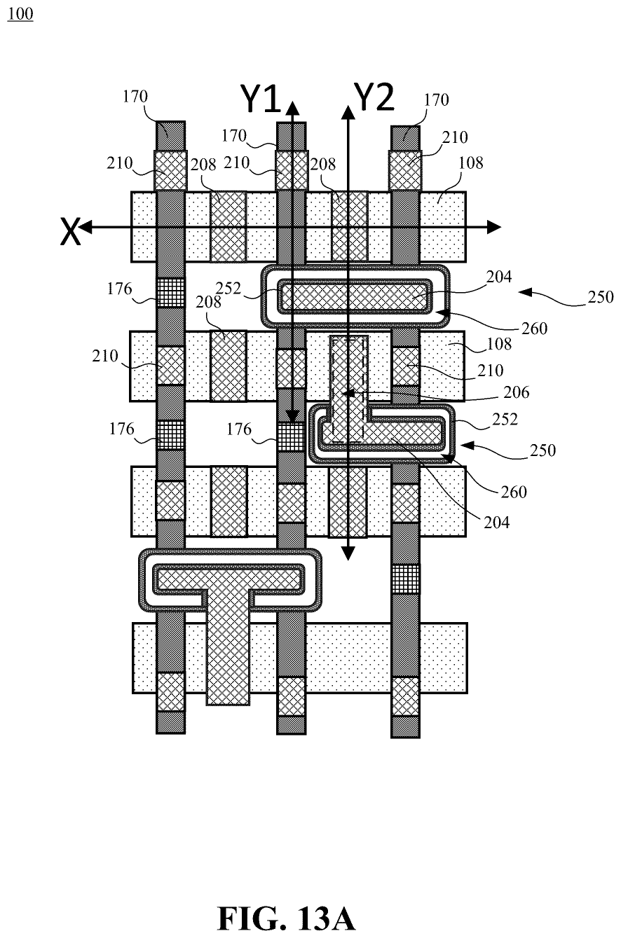

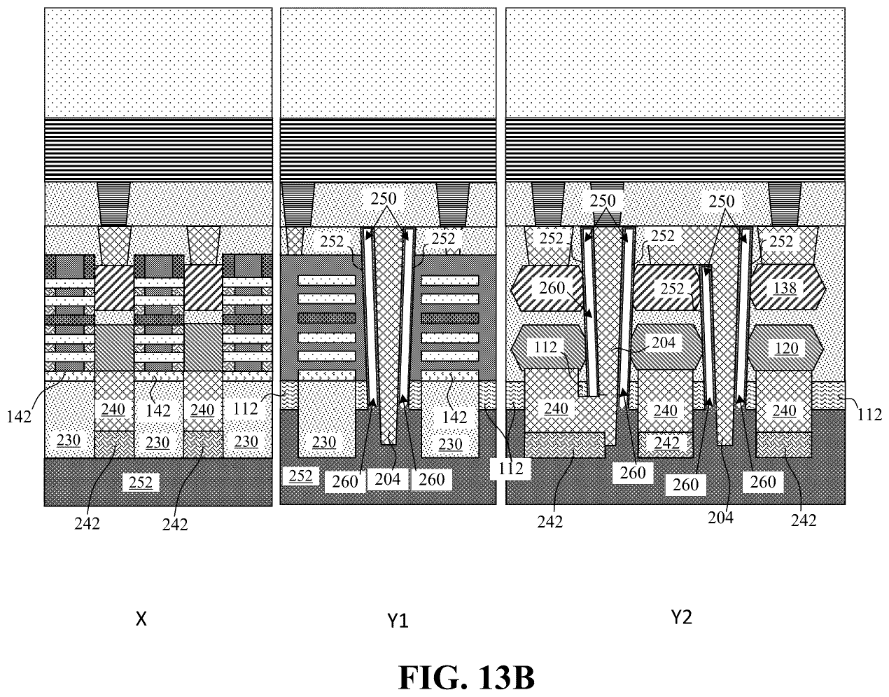

FIG. 13A and FIG. 13B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, backside ILD 252 may be formed and an airgap spacer 260 may be formed within the airgap opening 250.

Airgap spacer 260 may be a material void or airgap and is present around an associated deep via 204. The airgap spacer 260 may reduce the parasitic capacitance between the deep via 204 and the adjacent replacement gate structures 170 and/or may reduce the parasitic capacitance between the deep via 204 and the adjacent bottom/top source/drain regions 120, 138, relative to a deep via without an airgap spacer 260 therearound (e.g., a dielectric around the deep via).

In some embodiments, the airgap spacer 260 results from a deposition process of a backside ILD 252 in combination with a predefined relationship between an inlet or backside areal or area of the airgap opening 250. For example, when the inlet or backside areal or area is sufficiently small compared to the thickness of the deep via 204, the backside ILD 252 material accumulates on the sides of the airgap opening 250 more quickly than on the other surfaces, enabling the backside ILD 252 material to build up and close on itself at the respective inlet or backside areal or area of the airgap opening 250.

In this way, the backside ILD 252 material may fail to occupy a respective internal region of the airgap opening 250. As such, in one example, the material void or airgap of the airgap spacer 260 may be encapsulated by the backside ILD 252 material of the internal surfaces of the airgap opening 250, as depicted. As such, in another example, the material void or airgap of the airgap spacer 260 may be encapsulated by the backside ILD 252 material on some but not all internal surfaces of the airgap opening 250. As a result, the airgap spacer 260 may not include a fully encapsulating perimeter of backside ILD 252 material.

Different instances of airgap spacer 260 may have relative differences in shape, size, location, or the like, because of manufacturing tolerance effects and/or to independently improve or optimize parasitic capacitance decreases associated with the respective deep vias 204.

For clarity, while referred to as an “airgap” in this description, the airgap spacer 260 may contain gases different from those commonly associated with air and its composition. As such, airgap spacer 260 can also be referred to as a void, pocket, bubble, or other terminology. Also, the airgap spacer 260 can be distinguished from small imperfections that may be randomly positioned throughout a material, such as backside ILD 252, based on the airgap spacer 260 having a significantly greater size and being aligned between replacement gate structures 170 and adjacent source/drain regions 120, 138. Further, while illustrated in the Y cross-sectional views, as having a rectangular cross-sectional shape, such shape may not represent the actual shape and the airgap spacer 260 can have other cross-sectional shapes, including round, elliptical, trapezoidal, or other irregular or elongated shapes.

The backside ILD 252 material may continue to be deposited on the backside of the semiconductor IC device 100 after the pinching off thereof to form the airgap spacers 260 to a predetermined thickness. The backside ILD 252 may be formed by depositing a dielectric material that has a relatively poor ability to fill a high-aspect ratio airgap opening 250 so as to promote the pinching off thereof to form the airgap spacers 260. Any appropriate deposition technique for forming the backside ILD 252 can be utilized. Subsequently, a planarization process, such as a CMP process or a mechanical grinding process, may remove excess backside ILD 252 material. Therefore, the bottom surface of the backside ILD 252 may be substantially coplanar and/or substantially horizontal.

FIG. 14A and FIG. 14B depict respective partial top-down structure views and corresponding fabrication stage cross-section views of an illustrative semiconductor IC device 100 that is to include one or more airgap spacers around respective deep via portions of a contact, according to one or more embodiments of the disclosure. In the present fabrication stage, backside interconnects 270 may be formed and backside BEOL network 280 may be formed.

The backside interconnects 270 may be formed by patterning respective backside interconnect openings within the backside ILD 252 and backside contact caps 242 from the backside (i.e., from below the semiconductor IC device 100, as depicted, upward to respective structures thereof). The backside interconnects 270 may be in direct or indirect physical and electrical contact and/or may physically meld with respective material(s) of one or more regions of the semiconductor IC device 100. For example, a particular backside interconnect 270 may be in direct contact with the bottom source/drain region 120 and a particular backside interconnect 270 may be in direct contact with deep via 204.

The backside interconnects 270 may be formed by depositing conductive material(s) like the processes utilized to fabricate backside contacts 240. Subsequently, a CMP or other planarization process may planarize the respective bottom surfaces of backside interconnects 270 and the backside ILD 252. In embodiments, the backside interconnects 270 are fabricated in backside MOL fabrication operations and may be illustrations of MOL backside contacts. In other embodiments, as depicted, the backside interconnects 270 are interconnects within a lowest VIA level within the backside BEOL network 280.

Further in the depicted fabrication stage, the backside BEOL network 280 may be formed. The backside BEOL network 280 may be formed over the backside ILD 252, over the backside interconnects 270. The backside BEOL network 280 may be indirectly electrically and/or indirectly physically connected to the one or more S/D regions (e.g., bottom source/drain region 120, top source/drain region 132) by way of a particular backside contact or series of backside contacts.

The backside BEOL network 280 can include one or more interconnect dielectric material layers and contains backside conductive wires and/or interconnects, such as interconnects 270, embedded therein. In some embodiments, the backside wires within the backside BEOL network 280 may be composed of Cu. The backside BEOL network 280 can include “x” numbers of backside metal levels, wherein “x” is an integer starting from 1. If not included in frontside BEOL network 226, backside BEOL network 280 may further contain conductive pads that are connected to one or more of the backside conductive wires and may be used to connect the semiconductor IC device 100 to the external and/or higher-level structure.

In an example, signal routing and power routing is effectively split between the frontside BEOL network 226 and the backside BEOL network 280. For example, at least 90% of the backside conductive wires that are in metal levels closest to the transistor(s) are power routing wires. Power routing wires may be less dense signal routing wires. A signal routing wire is defined herein as a conductive feature, such as a wire, trace, or the like, that is configured to electrically carry a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like. For clarity, in some examples, the backside BEOL network 280 may be a backside power distribution network (BSPDN).

The backside BEOL network 280 includes various wiring levels. The wiring levels may alternate between an interconnect level and a wire level. To form an interconnect level, an associated dielectric passivation layer may be formed, the dielectric passivation layer may be patterned to create an interconnect opening therein, and conductive or metal material may be deposited within the interconnect opening to form the interconnect. To form a wire level, an associated dielectric passivation layer may be formed, the dielectric passivation layer may be patterned to create a wiring trench therein, and conductive or metal material may be deposited within the wiring trench to form a wire. A wire, such as within a lowest wire level may connect directly to one or more backside interconnects 270.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

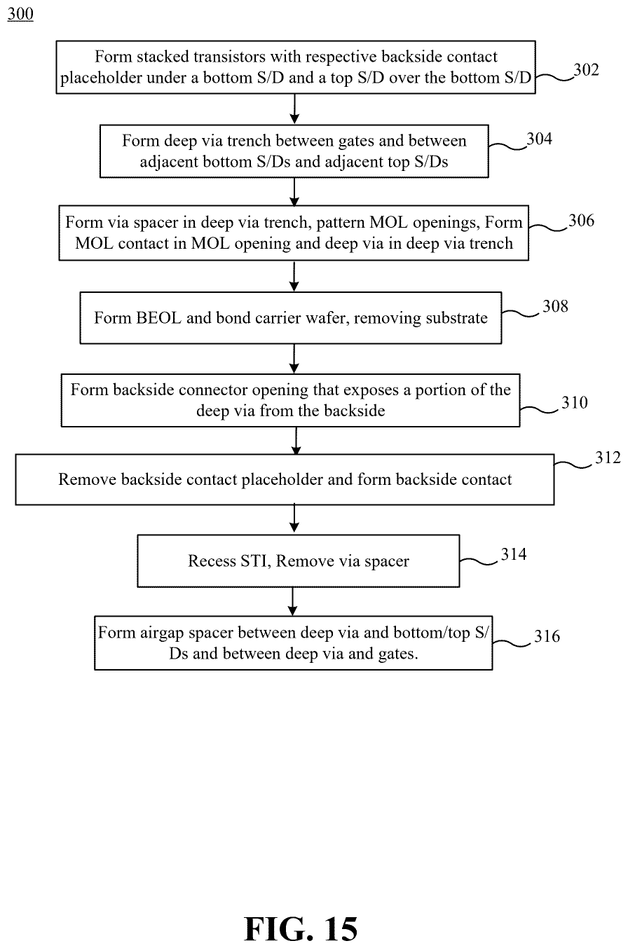

FIG. 15 depicts a flow diagram illustrating a method 300 to fabricate a semiconductor IC device, such as semiconductor IC device 100. The depicted fabrication operations of method 300 may be illustratively depicted and described above with reference to one or more of FIG. 2A through FIG. 14B of the drawings, which describe the fabrication of semiconductor IC device 100. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming stacked transistors (e.g., a stacked FET) that respectively includes a backside contact placeholder under a bottom source/drain region and further includes a top source/drain region above the bottom source/drain region.

At block 304, method 300 may continue with forming a deep via trench between adjacent gates, between adjacent bottom source/drain regions, and between adjacent top source/drain regions.

At block 306, method 300 may continue with forming a via spacer in the deep via trench, with patterning frontside contact (e.g., MOL) openings, with forming a frontside contact within a respective frontside contact opening and with forming a deep via within the deep via trench. For clarity, one of the frontside contact opening may intersect with the deep via trench and a contact that includes an integrated frontside contact (i.e., the extension region of the applicable contact) and deep via may be formed.

At block 308, method 300 may continue with forming a frontside BEOL network, bonding a carrier wafer thereto, and with removing a backside substrate associated with the stacked transistors.

At block 310, method 300 may continue with forming a backside contact opening that exposes a portion of the deep via.

At block 312, method 300 may continue with forming removing the backside contact placeholder and forming a backside contact. The backside contact may be formed directly against the exposed deep via and directly against a bottom source/drain. Alternatively, the backside contact may be formed directly against a bottom source/drain and is not associated with a deep via.

At block 314, method 300 may continue with recessing one or more shallow trench isolation regions to expose the via spacer and with removing the via spacer.

At block 316, method 300 may continue with forming airgap spacer around the deep via in place of the removed via spacer. The airgap spacer may be between the deep via and the adjacent replacement gate structures, between the deep via and the adjacent bottom source/drains, and/or between the deep via and the adjacent top source/drains. The airgap spacers may reduce the parasitic capacitance between the deep via and the replacement gate structures and/or between the deep via and the source/drains.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a bottom source/drain region and a top source/drain region stacked above the bottom source/drain region;
a conductive contact comprising a deep via that is adjacent to both the bottom source/drain region and the top source/drain region and an extension region that laterally protrudes from the deep via; and
an airgap spacer in contact with the bottom source/drain region, in contact with the top source/drain region, and in contact with the deep via.

2. The semiconductor IC device of claim 1, further comprising:
a common gate that controls respective charge carrier flow to/from both the bottom source/drain region and the top source/drain region;
wherein the deep via is further adjacent to the common gate; and
wherein the airgap spacer is further in contact with the common gate.

3. The semiconductor IC device of claim 2, wherein a top surface of the airgap spacer is above a top surface of the top source/drain region and a top surface of the common gate.

4. The semiconductor IC device of claim 3, wherein a bottom surface of the airgap spacer is below a bottom surface of the bottom source/drain region and a bottom surface of the common gate.

5. The semiconductor IC device of claim 2, further comprising:
a frontside gate contact connected to the common gate; and
a frontside back end of line (BEOL) network connected to the frontside gate contact by a gate interconnect.

6. The semiconductor IC device of claim 5, wherein a top surface of the airgap spacer is substantially coplanar with a bottom surface of the gate interconnect.

7. The semiconductor IC device of claim 2, further comprising:
a shallow trench isolation (STI) region underneath the common gate and below and adjacent to the bottom source/drain region;
wherein the deep via is further adjacent to the STI region; and
wherein the airgap spacer is further in contact with the STI region.

8. The semiconductor IC device of claim 7, further comprising:
a backside interlayer dielectric (ILD) underneath the STI region and in contact with the deep via; and
wherein a pinch-off region of the backside ILD defines a bottom surface of the airgap spacer.

9. The semiconductor IC device of claim 8, wherein the pinch-off region of the backside ILD is between a bottom surface of the STI region and a top surface of the STI region.

10. The semiconductor IC device of claim 1, wherein the extension region is directly coupled against a top surface of the top source/drain region.

11. The semiconductor IC device of claim 1, wherein the extension region is directly coupled against a bottom surface of the bottom source/drain region.

12. A semiconductor integrated circuit (IC) device comprising:
a first stacked transistor comprising a first bottom source/drain region and first top source/drain region stacked above the first bottom source/drain region;
a second stacked transistor comprising a second bottom source/drain region and second top source/drain region stacked above the second bottom source/drain region;
a conductive contact comprising a deep via that is between the first stacked transistor and the second stacked transistor and an extension region that laterally protrudes from the deep via; and
an airgap spacer around the deep via and in contact with the first bottom source/drain region, in contact with the first top source/drain region, in contact with the second bottom source/drain region, and in contact with the second top source/drain region.

13. The semiconductor IC device of claim 12, further comprising:
a first common gate that controls respective charge carrier flow to/from both the first bottom source/drain region and the first top source/drain region; and
a second common gate that controls respective charge carrier flow to/from both the second bottom source/drain region and the second top source/drain region;
wherein the deep via is further between the first common gate and the second common gate; and
wherein the airgap spacer is further in contact with the first common gate and the second common gate.

14. The semiconductor IC device of claim 13, wherein a top surface of the airgap spacer is above a top surface of the first and second top source/drain regions and a top surface of the first and second common gates.

15. The semiconductor IC device of claim 14, wherein a bottom surface of the airgap spacer is below a bottom surface of the first and second bottom source/drain regions and a bottom surface of the first and second common gates.

16. The semiconductor IC device of claim 13, further comprising:
a first frontside gate contact connected to the first common gate;
a second frontside gate contact connected to the second common gate; and
a frontside back end of line (BEOL) network connected to the first frontside gate contact by a first gate interconnect and connected to the second frontside gate contact by a second gate interconnect.

17. The semiconductor IC device of claim 16, wherein a top surface of the airgap spacer is substantially coplanar with a bottom surface of the first and second gate interconnects.

18. The semiconductor IC device of claim 13, further comprising:
a shallow trench isolation (STI) region underneath the first and second common gates and below and between the first and second bottom source/drain regions;
wherein a bottom surface of the deep via is below a bottom surface of the STI region; and
wherein the airgap spacer is further in contact with the STI region.

19. The semiconductor IC device of claim 18, further comprising:
a backside interlayer dielectric (ILD) underneath the STI region and in contact with the deep via;
wherein a pinch-off region of the backside ILD defines a bottom surface of the airgap spacer.

20. A method of fabricating a semiconductor integrated circuit (IC) device comprising:
forming a deep via trench between a first stacked transistor and a second stacked transistor;
forming a via spacer around a perimeter within the deep via trench;
removing the via spacer to form an airgap spacer opening; and
forming a backside interlayer dielectric (ILD) that pinches off within the airgap spacer opening and forms an airgap spacer around the deep via contact region.
